(19) United States
(12) Patent Application Publication
(10) Pub. No.: US 2026/0035260 A1
(43) Pub. Date: Feb. 5, 2026

(54) COMPOSITE MATERIAL, PREPARATION METHOD THEREOF, AND OPTOELECTRONIC DEVICE

(71) Applicants: Guangdong Juhua Research Institute of Advanced Display, Guangzhou (CN); Shenzhen TCL High-Tech Development Co., Ltd., Shenzhen (CN)

(72) Inventors: Jiehao GUAN, Guangzhou (CN); Jiaqing ZHUANG, Guangzhou (CN); Haikun LIU, Guangzhou (CN)

(73) Assignees: Guangdong Juhua Research Institute of Advanced Display, Guangzhou (CN); Shenzhen TCL High-Tech Development Co., Ltd., Shenzhen (CN)

(21) Appl. No.: 19/281,538

(22) Filed: Jul. 25, 2025

(30) Foreign Application Priority Data
Aug. 5, 2024 (CN) 202411069412.0

(51) Int. Cl. C01G 9/02; H10K 50/115; H10K 50/15; H10K 50/16; H10K 50/81; H10K 50/82

(52) U.S. Cl. CPC C01G 9/02; H10K 50/115; H10K 50/15; H10K 50/16; H10K 50/81; H10K 50/82; C01P 2004/64; C01P 2004/84; C01P 2006/40

(57) ABSTRACT

The present disclosure provides a composite material, a preparation method thereof and an optoelectronic device. The composite material includes a metal oxide nanoparticle and a shell layer coated on a surface of the metal oxide nanoparticle, a material of the shell layer including an alkali metal halide. In the composite material, the surface of the metal oxide nanoparticle is coated with the alkali metal halide, which is helpful to improve the stability of the metal oxide nanoparticle in the electrification process and reduce electrochemical changes.

This application claims priority to Chinese Application No. 202411069412.0, entitled “COMPOSITE MATERIAL, PREPARATION METHOD THEREOF, THIN FILM OPTOELECTRONIC DEVICE AND DISPLAY DEVICE”, filed on Aug. 5, 2024. The entire disclosures of the above application are incorporated herein by reference.

### TECHNICAL FIELD

The present disclosure relates to a technical field of semiconductors, in particular to a composite material, a preparation method thereof and an optoelectronic device.

### BACKGROUND

Metal oxides are a kind of electronic materials with semiconductor properties that can be used to make semiconductor devices and integrated circuits, such as zinc oxide nanoparticles, titanium dioxide nanoparticles, tin oxide nanoparticles and so on. However, in practical applications, it has been found that metal oxides are easily affected by the water-oxygen environment, resulting in their performance degradation.

### SUMMARY

In view of this, the present disclosure provides a composite material, a preparation method thereof and an optoelectronic device.

Embodiments of the present disclosure is realized as follows.

In a first aspect, the present disclosure provides a composite material including a metal oxide nanoparticle and a shell layer coated on a surface of the metal oxide nanoparticle, a material of the shell layer including an alkali metal halide.

In a second aspect, the present disclosure provides a method of preparing a composite material, including: providing a mixed solution, wherein the mixed solution includes a metal oxide nanoparticle, an alkali metal halide, and an organic solvent; and heating the mixed solution to obtain a composite material.

In a third aspect, the present disclosure provides an optoelectronic device including an anode, an electronic functional layer, and a cathode disposed in a stack. The electronic functional layer includes a thin film, a material of the thin film including a composite material that includes a metal oxide nanoparticle and a shell layer coated on a surface of the metal oxide nanoparticle, a material of the shell layer including an alkali metal halide.

### BRIEF DESCRIPTION OF DRAWINGS

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a schematic structural diagram of a composite material according to an embodiment of the present disclosure.

FIG. 2 is a schematic structural diagram of an optoelectronic device according to an embodiment of the present disclosure.

FIG. 3 is a flow chart of a method of preparing a composite material according to an embodiment of the present disclosure.

### DETAILED DESCRIPTION

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure. Furthermore, it should be understood that the detailed description described herein is for illustration and explanation of the present disclosure only, and is not intended to limit the present disclosure. In the present disclosure, unless otherwise stated, location words such as “upper” and “lower” are used to specifically refer to the plane direction in the drawings. Additionally, in the description of the present disclosure, the term “including” means “including but not limited to”. Various embodiments of the present disclosure may exist in a range of forms. It should be understood that the description in a range form is for convenience and brevity only, and should not be construed as a hard limitation on the scope of the present disclosure. Accordingly, it should be considered that the stated range description has specifically disclosed all possible sub-ranges as well as single numerical values within the range. For example, it should be considered that a range from 1 to 6 has specifically disclosed subranges, such as from 1 to 3, from 1 to 4, from 1 to 5, from 2 to 4, from 2 to 6, from 3 to 6, and the like, and single numbers within the range, such as 1, 2, 3, 4, 5, and 6, which apply regardless of the range. In addition, whenever a numerical range is indicated herein, it is meant to include any referenced number (fraction or integer) within the indicated range.

In the present disclosure, “and/or” describes the association relationship of the association object, and indicates that there may be three kinds of relationships, for example, A and/or B, which may indicate that A exists alone, A and B exist at the same time, and B exists alone. A and B may be singular or plural.

In the present disclosure, “at least one” refers to one or more, and “a plurality” refers to two or more. “at least one of the following”, or similar expressions thereof refer to any combination of these items, including any combination of single or plural items. For example, “at least one of a, b, or c”, or “at least one of a, b, and c” may all mean: a, b, c, a-b (that is, a and b), a-c, b-c, or a-b-c, wherein a, b, and c, may be a single item or a plurality of items, respectively.

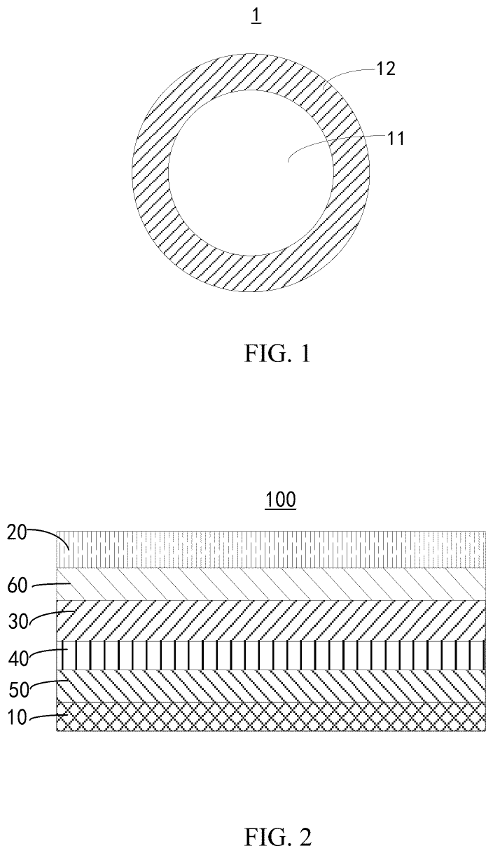

In a first aspect, the present disclosure provides a composite material 1. Refer to FIG. 1, the composite material 1 includes a metal oxide nanoparticle 11 and a shell layer 12 coated on a surface of the metal oxide nanoparticle 11. A material of the shell layer 12 includes an alkali metal halide.

Metal oxides are easily affected by the water and oxygen environment, resulting in their performance degradation. In addition, after the nanoparticle film is formed, under the action of heating or electrothermal, the chemical interaction between the nanoparticles will lead to the crosslinking of the nanoparticles and the growth of crystallite, which will lead to the change of the properties of the nanoparticles. In this regard, the present disclosure proposes the composite material 1. By coating the surface of the metal oxide nanoparticle 11 with the alkali metal halide, it is possible to reduce the adverse effects of water, oxygen and other substances on the metal oxide, reduce the fusion change of the nanoparticles caused by the thermal effect in a heating or electrothermal environment, and help to improve the stability of the composite material in the electrification process and reduce the electrochemical change. When the composite material 1 is used in the optoelectronic device 100, the performance of the device may be improved. In addition, by adjusting a thickness of the shell layer 12 composed of the alkali metal halide, the tunneling of electrons may be adjusted, thereby improving the electron injection ability of the composite material. When the composite material 1 is used in the optoelectronic device 100, the potential barrier of electron injection from the electrode to the light-emitting layer 30 may be reduced, the injection of electrons may be improved, and the efficiency of the device may be improved.

In some embodiments, in the composite material 1, an alkali metal element is doped on the surface of the metal oxide nanoparticle 11, and at the same time, halogen elements occupy some oxygen vacancies of the metal oxide, thereby forming a metal oxide-alkali metal halide transition layer between the core composed of the metal oxide nanoparticle 11 and the shell layer composed of the alkali metal halide.

In some embodiments, the metal oxide nanoparticle includes one or more of an undoped oxide and a doped oxide; the undoped oxide includes at least one of ZnO, TiO₂, SnO₂, Ga₂O₃, and Al₂O₃, an oxide in the doped oxide includes at least one of ZnO, TiO₂, SnO₂, Ga₂O₃, and Al₂O₃, and a doping element in the doped oxide includes at least one of Al, Mg, Li, In, and Ga.

The alkali metal halide may include an alkali metal cation and a halogen anion, the alkali metal cation includes one or more of Na⁺, K⁺, Li⁺, Rb⁺, Cs⁺, and Fr⁺, and the halogen anion includes one or more of F⁻, Cl⁻, Br⁻, and I⁻. For example, the alkali metal halide may include, but is not limited to, one or more of NaF, NaCl, NaBr, NaI, KF, KCl, KBr, KI, LiF, LiCl, LiBr, Lil, RbF, RbCl, RbBr, RbI, CsF, CsCl, CsBr, CsI, FrF, FrCl, FrBr, and FrI.

In some embodiments, the alkali metal halide may include one or more of alkali metal fluoride, which may be NaF, KF, LIF, RbF, CsF, FrF, or the like. NaF, KF, LiF, RbF, CsF and FrF have relatively good stability to water, oxygen, heat and electric fields, and have certain ability to regulate the electron tunneling of metal oxides.

In other embodiments, the metal oxide nanoparticle 11 is a ZnO nanoparticle, and the shell layer 12 is a NaF shell layer, that is, the composite material 1 is composed of a ZnO nanoparticle and a NaF shell layer coated on the surface of the ZnO nanoparticle, and is described as ZnO @ NaF. ZnO @ NaF has better stability to water, oxygen, heat, electric field, etc. and has adjustable electron tunneling.

In some embodiments, an average particle size of the metal oxide nanoparticles 11 ranges from 3 nm to 12 nm. For example, the average particle size may be 3 nm, 4 nm, 5 nm, 6 nm, 7 nm, 8 nm, 9 nm, 10 nm, 11 nm, 12 nm or a value between any two of the above values.

In some embodiments, a thickness of the shell layer 12 ranges from 0.3 nm to 5 nm. For example, it may be 0.3 nm, 0.5 nm, 1 nm, 2 nm, 3 nm, 4 nm, 5 nm, or a value between any two of the above values.

In some embodiments, an average particle size of the composite material 1 ranges from 3.3 nm to 17 nm. For example, it may be 3.3 nm, 4 nm, 5 nm, 6 nm, 7 nm, 8 nm, 9 nm, 10 nm, 11 nm, 12 nm, 13 nm, 14 nm, 15 nm, 16 nm, 17 nm or a value between any two of the above values. In other embodiments, the average particle size of the composite material 1 is 4 to 13 nm.

It will be appreciated that the average particle size mentioned herein may be detected by transmission electron microscopy (TEM).

It can be understood that the surface of the shell layer 12 may be further coated with other shell layers, such as metal oxide materials such as tin dioxide and titanium dioxide.

In a second aspect, the present disclosure also provides a method of preparing a composite material 1, which can prepare the composite material 1 having a metal oxide nanoparticle 11 as a core and an alkali metal halide as a shell layer 12, and the composite material 1 has better stability to water, oxygen, heat, electric field, and the like and adjustable electron tunneling property. The composite material 1 may be the composite material 1 described above, having the characteristics of the composite material 1 described above.

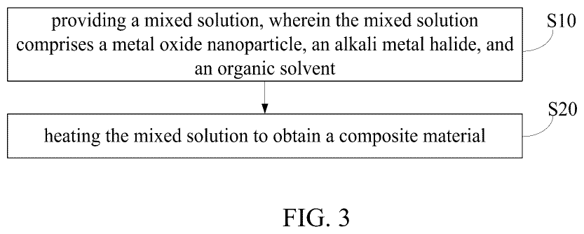

Referring to FIG. 3, in some embodiments, the method including:
S10, providing a mixed solution, wherein the mixed solution includes a metal oxide nanoparticle 11, an alkali metal halide, and an organic solvent; and
S20, heating the mixed solution to obtain a composite material 1.

In step S10, in some embodiments, the metal oxide nanoparticle 11 includes one or more of an undoped oxide and a doped oxide; the undoped oxide includes at least one of ZnO, TiO₂, SnO₂, Ga₂O₃, and Al₂O₃, an oxide in the doped oxide includes at least one of ZnO, TiO₂, SnO₂, Ga₂O₃, and Al₂O₃, and a doping element in the doped oxide includes at least one of Al, Mg, Li, In, and Ga.

In step S10, in some embodiments, the metal oxide nanoparticle 11 includes one or more of an undoped oxide and a doped oxide; the undoped oxide includes at least one of ZnO, TiO₂, SnO₂, Ga₂O₃, and Al₂O₃, an oxide in the doped oxide includes at least one of ZnO, TiO₂, SnO₂, Ga₂O₃, and Al₂O₃, and a doping element in the doped oxide includes at least one of Al, Mg, Li, In, and Ga.

In some embodiments, the organic solvent includes one or more of C₈-C₁₈ organic acids. The C₈-C₁₈ organic acids include one or more of octanoic acid, capric acid, heptanoic acid, oleic acid, stearic acid, lauric acid, myristic acid, and palmitic acid. It is understood that stearic acid, lauric acid, myristic acid, palmitic acid, etc. may be used as a solvent after being melted by heating, or may be directly mixed with the alkali metal halide or the like, and then heated to form the mixed solution.

In the mixed system of the metal oxide nanoparticle 11, the alkali metal halide and the organic solvent, the organic solvent provides a liquid reaction environment, and its organic acid anion may react with alkali metal ion to form a salt, so that the alkali metal element may be incorporated into the surface of the metal oxide nanoparticle 11, and at the same time, it may be used as a coordination solvent to stabilize the nanoparticle and regulate the reaction activity through steric hindrance.

In some embodiments, a molar ratio of the alkali metal halide to the metal element in the metal oxide nanoparticle 11 is 1:2-4. For example, it may be 1:2, 1:2.2, 1:2.5, 1:2.8, 1:3, 1:3.3, 1:3.5, 1:3.7, 1:4, or a value between any two of the above values.

In some embodiments, prior to the step S10, the method further includes a step of preparing the mixed solution, and the step of preparing the mixed solution including:
S101, mixing the metal precursor and the first solvent to obtain a first mixture containing an organometallic complex;
S102, mixing a second solvent and the first mixture to obtain a second mixture containing a metal oxide nanoparticle 11; and
S103, mixing the second mixture, an alkali metal halide and an organic solvent to obtain the mixed solution containing the metal oxide nanoparticle 11, the alkali metal halide and the organic solvent.

In step S101, the first solvent may include one or more of octadecene, paraffin oil, tetrahydrofuran, disilicone oil, octafluorocyclohexane, and polycyclopentadiene;
the metal precursor may include an organic acid salt containing a metal element, the metal element including at least one of Zn, Ti, Sn, Ga, Al, Mg, Li, In, and Ga, and the organic acid radical in the organic acid salt includes at least one of stearate ion, oleate ion, laurate ion, myristic ion, and palmitic ion. For example, the Zn precursor may be one or more of zinc oleate, zinc stearate, zinc dilaurate, zinc myristate, and zinc dipalmitate.

In some embodiments, a molar ratio of the first solvent to the metal element in the metal precursor is 2.2-3:1. For example, it may be 2.2:1, 2.3:1, 2.4:1, 2.5:1, 2.6:1, 2.7:1, 2.8:1, 2.9:1, 3:1, or a value between any two of the above values. By adjusting the molar ratio, the reaction rate and the activity of the monomer may be effectively adjusted.

In some embodiments, the step S101 may be performed by mixing the metal precursor and the first solvent at a first temperature in a vacuum room for a first time period, and injecting inert gas into the vacuum room to make the metal precursor reacting with the first solvent at a second temperature for a second time period.

The first temperature ranges from 120° C. to 140° C., and may be, for example, 120° C., 125° C., 130° C., 135° C., 140° C., or a value between any two of the above values. The second temperature ranges from 270° C. to 290° C., and may be, for example, 270° C., 275° C., 280° C., 285° C., 290° C., or a value between any two of the above values.

In some embodiments, the first time period maybe range from 25 minutes to 60 minutes. For example, it may be 25 min, 30 min, 35 min, 40 min, 45 min, 50 min, 55 min, 60 min, or a value between any two of the above values.

In some embodiments, the second time period may be 25-60 minutes. For example, it may be 25 min, 30 min, 35 min, 40 min, 45 min, 50 min, 55 min, 60 min, or a value between any two of the above values.

In some embodiments, the inert gas may include, but is not limited to, one or more of nitrogen, argon, and helium.

By mixing the metal precursor and the first solvent at the first temperature in the vacuum room, impurities such as water and short-chain organic matter in the reaction system may be removed to a certain extent. Further, at the second temperature, the metal precursor undergoes a complexation reaction with the first solvent to form an organometallic complex.

Returning to S10, the amount of the organic solvent may be: a molar ratio of the organic solvent to the first solvent may be 1:1 to 1:1.2. For example, it may be 1:1, 1:1.1, 1:1.2, or a value between any two of the above values.

In step S102, the second solvent may include a mixed solution of an alcohol compound and an A solvent, the alcohol compound includes one or more of C₆-C₁₈ alcohol compounds including one or more of hexanol, octanol, dodecanol, tetradecanol, cetyl alcohol, and stearyl alcohol, and the A solvent includes one or more of octadecene, paraffin oil, tetrahydrofuran, disilicone oil, octafluorocyclohexane, and polycyclopentadiene.

The second solvent may stimulate the activity of the metal precursor and promote its nucleation reaction. At the same time, by adjusting a ratio of the alcohol compound to the A solvent, the reaction rate and reactant activity may be adjusted.

In some embodiments, the second solvent may be obtained by dissolving the alcohol compound in the A solvent, and a concentration of the alcohol compound in the mixed solution may be 0.8-1.2 mmol/g. In order to facilitate better dissolution of the alcohol compound, the dissolution process may be carried out under heating conditions, and the heating temperature may be 180° C. to 200° C.

In some embodiments, step S102 may specifically include:
S1021, mixing the second solvent and the first mixture in a third temperature for a third time period to obtain a reaction mixture;
S1022, mixing a third solvent and the reaction mixture in a fourth temperature for a fourth time period to obtain a third mixture containing a metal oxide nanoparticle 11.

In some embodiments, the third temperature ranges from 240° C. to 260° C. For example, it may be 240° C., 245° C., 250° C., 255° C., 260° C., or a value between any two of the above values.

In some embodiments, the third time period ranges from 5 minutes to 10 minutes. For example, it may be 5 min, 6 min, 7 min, 8 min, 9 min, 10 min, or a value between any two of the above values.

In some embodiments, the third solvent includes a mixed solution of an acid compound and a B solvent, the acid compound includes one or more of C₈-C₁₈ organic acids including one or more of octanoic acid, capric acid, heptanoic acid, oleic acid, stearic acid, lauric acid, myristic acid, and palmitic acid, and the B solvent includes one or more of octadecene, paraffin oil, tetrahydrofuran, disilicone oil, octafluorocyclohexane, and polycyclopentadiene. In some embodiments, the third solvent may be obtained by dissolving the acid compound in the B solvent, and a concentration of the acid compound in the mixed solution may be 0.3-0.5 mmol/g. In order to facilitate better dissolution of the acid compound, the dissolution process may be carried out under heating conditions, and the heating temperature may be 110° C. to 130° C.

Introducing some free ligand fatty acids into the reaction system may stabilize the reactive monomers reconstituted during the ripening reaction, regulate the reactivity of the ripening reaction, and then control the shape and size of the product nanocrystals.

In some embodiments, the fourth temperature ranges from 240° C. to 260° C. For example, it may be 240° C., 245° C., 250° C., 255° C., 260° C., or a value between any two of the above values.

In some embodiments, the fourth time period ranges from 60 minutes to 90 minutes. For example, it may be 60 min, 65 min, 70 min, 75 min, 80 min, 85 min, 90 min, or a value between any two of the above values.

In some embodiments, a molar ratio of the alcohol compound in the second solvent to the metal element in the metal precursor is 1:0.15-0.25. For example, it may be 1:0.15, 1:0.16, 1:0.17, 1:0.18, 1:0.19, 1:0.2, 1:0.21, 1:0.22, 1:0.23, 1:0.24, 1:0.25, or a value between any two of the above values.

In some embodiments, a molar ratio of the acid compound in the third solvent to the metal element in the metal precursor is 1:0.8-1. For example, it may be 1:0.8, 1:0.82, 1:0.85, 1:0.88, 1:0.9, 1:0.93, 1:0.95, 1:0.97, 1:1, or a value between any two of the above values.

In some embodiments, the A solvent, the B solvent, and the first solvent may be selected from the same kind of compound.

In step S20, a temperature range for heating is from 260° C. to 300° C. For example, it may be 260° C., 265° C., 270° C., 275° C., 280° C., 285° C., 290° C., 295° C., 300° C., or a value between any two of the above values. Controlling within this temperature range may promote the reaction kinetics of materials, promote the growth and particle size control of materials.

In some embodiments, a time range for heating is 60-90 minutes. For example, it may be 60 min, 65 min, 70 min, 75 min, 80 min, 85 min, 90 min, or a value between any two of the above values.

In a third aspect, the present disclosure also provides a thin film wherein a material of the thin film is the composite material 1 prepared by the method described above, or includes the composite material 1 described above. The thin film has better thermal stability and water-oxygen stability, and has better electron tunneling characteristics, and may be used as the electronic functional layer 60 of the optoelectronic device 100.

In a fourth aspect, the present disclosure also provides an optoelectronic device 100 including, but not limited to, an organic light emitting diode, a quantum dot light emitting diode, a photovoltaic cell, a photodetector, and the like. The optoelectronic device 100 may be an upright device or an inverted device. Referring to FIG. 2, the optoelectronic device 100 includes an anode 10, a cathode 20, and an electronic functional layer 60 disposed between the anode 10 and the cathode 20, and the electronic functional layer 60 includes a thin film as described above. A material of the electronic functional layer 60 is the composite material 1 prepared by the method described above, or includes the composite material 1 described above.

The present disclosure proposes the composite material 1. By coating the surface of the metal oxide nanoparticle 11 with the alkali metal halide, it is possible to reduce the adverse effects of water, oxygen and other substances on the metal oxide, reduce the fusion change of the nanoparticles caused by the thermal effect in a heating or electrothermal environment, and help to improve the stability of the composite material in the electrification process and reduce the electrochemical change. When the composite material 1 is used in the optoelectronic device 100, the performance of the device may be improved. In addition, by adjusting a thickness of the shell layer 12 composed of the alkali metal halide, the tunneling of electrons may be adjusted, thereby improving the electron injection ability of the composite material. When the composite material 1 is used in the optoelectronic device 100, the potential barrier of electron injection from the electrode to the light-emitting layer 30 may be reduced, the injection of electrons may be improved, and the efficiency of the device may be improved.

The anode 10 and the cathode 20 are each independently selected from one of a doped metal oxide particle electrode, a composite electrode of metal and metal oxide, a graphene electrode, a carbon nanotube electrode, a metal electrode or an alloy electrode, and a material of the doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide, the composite electrode of metal and metal oxide is selected from AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, and a material of the metal electrode is selected from one or more of Ag, Al, Cu, Mo, Au, Pt, Si, Ca, Mg and Ba. Here, “/” represents a laminated structure, and for example, the composite electrode AZO/Ag/AZO represents an electrode having a composite structure in which three layers consisting of an AZO layer, an Ag layer and an AZO layer are stacked.

In addition to the anode 10 and the cathode 20, the optoelectronic device 100 may have other interlayer layers disposed between the anode 10 and the cathode 20, and may include, for example, but not limited to, a hole functional layer, a light-emitting layer 30, and the like. The light-emitting layer 30 may be disposed between the electronic functional layer 60 and the anode 10. The hole functional layer may be disposed between the anode 10 and the light-emitting layer 30. The hole functional layer includes one or both of a hole injection layer 50 and a hole transport layer 40, and the hole injection layer 50 is disposed between the hole transport layer 40 and the anode 10. When the optoelectronic device 100 includes the hole transport layer 40, the hole injection layer 50, and the light-emitting layer 30 at the same time, the film structure of the optoelectronic device 100 is as follows: the anode 10, the hole injection layer 50, the hole transport layer 40, the light-emitting layer 30, the electron functional layer 60, and the cathode 20 are stacked in this order, or the cathode 20, the electron functional layer 60, the light-emitting layer 30, the hole transport layer 40, the hole injection layer 50, and the anode 10 are stacked in this order. It can be understood that when one or more of the above-described film layers are omitted, the remaining film layers are still disposed in the above-described stacking order, for example, when the optoelectronic device 100 does not include the light-emitting layer 30, the remaining film layers contained therein are stacked in the following order: the anode 10, the hole injection layer 50, the hole transport layer 40, the electron functional layer 60, the cathode 20 are stacked in this order, or the cathode 20, the electron functional layer 60, the hole transport layer 40, the hole injection layer 50, the anode 10 are stacked in this order.

A material of the light-emitting layer 30 may be a conventional light-emitting material in the art, such as an organic light-emitting material or a quantum dot light-emitting material. The organic light-emitting materials are selected from one or more of 4,4′-bis(N-carbazole)-1,1′-biphenyl: tris[2-(p-tolyl)pyridine]iridium (III), 4,4′,4″-tris(carbazole-9-yl) triphenylamine: tris[2-(p-tolyl)pyridine]iridium, diarylanthracene derivatives, stilbene aromatic derivative, pyrene derivative, fluorene derivative, TBPe fluorescent material, TTPX fluorescent material, TBRb fluorescent material, DBP fluorescent material, delayed fluorescent material, TTA material, thermal activation delayed material, polymers containing B-N covalent bonding, hybrid local charge transfer excited state material, and exciplex luminescent material; the quantum dot light-emitting materials are selected from at least one of a single structure quantum dot, a core-shell structure quantum dot, and a perovskite type semiconductor material, and the core-shell structure quantum dot has one or more shell layers; a material of the single structure quantum dot, a core material of the core-shell structure quantum dot, and a shell material of the core-shell structure quantum dot are selected from at least one of a Group II-VI compound, a Group IV-VI compound, a Group III-V compound, and a Group I-III-VI compound; the Group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the Group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the Group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the Group I-III-VI compound is selected from one or more of CuInS₂, CuInSe₂, and AgInS₂. As an example, the core-shell structure quantum dot may be selected from but not limited to at least one of CdZnSe/CdZnSe/ZnSe/CdZnS/ZnS, CdZnSe/CdZnSe/CdZnS/ZnS. CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS. For a material of the single structure quantum dot, a core material of the core-shell structure quantum dot, or the shell material of the core-shell structure quantum dot, the chemical formula provided only indicates the elemental composition and does not indicate the content of each element. For example, CdZnSe only indicates that a material is composed of three elements: Cd, Zn and Se. If it indicates the content of each element, it corresponds to CdₓZn₁₋ₓSe, 0<x<1. The perovskite type semiconductor is selected from one of a doped inorganic perovskite type semiconductor, an undoped inorganic perovskite type semiconductor, and an organic-inorganic hybrid perovskite type semiconductor, a general structure formula of the inorganic perovskite type semiconductor is AMX₃, wherein A is Cs⁺, M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺. Yb²⁺ and Eu²⁺. X is a halogen anion selected from one of Cl⁻, Br⁻, and I⁻; a general structure formula of the organic-inorganic hybrid perovskite type semiconductor is BMX₃, wherein B is an organic amine cation selected from CH₃(CH₂)ₙ₋₂NH₃⁺ (n≥2) or NH₃(CH₂)ₙNH₃²⁺ (n≥2), M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻.

A material of the hole functional layer may be a hole injection material or a hole transport material commonly used in the optoelectronic device 100 in the art. The hole transport material may include, but are not limited to, one or more of 4,4′-N,N′-dicarbazolyl-biphenyl (CBP), poly[(9,9′-dioctylfluorene-2,7-diyl)-co-(4,4′-(N-(4-sec-butylphenyl)diphenylamine)] (TFB), N,N′-diphenyl-N,N′-bis(1-naphthyl)-1,1′-biphenyl-4,4′-diamine (α-NPD), N,N′-diphenyl-N,N′-bis(3-methylphenyl)-(1,1′-biphenyl)-4,4′-diamine (TPD), N,N′-bis(3-methylphenyl)-N,N′-bis(phenyl)-spiro(spiro-TPD), N,N′-bis(4-(N,N′-diphenyl-amino)phenyl)-N,N′-diphenylbenzidine (DNTPD), 4,4′,4″-Tris(N-3-methylphenyl-N-phenylamino)triphenylamine (m-MTDATA), Poly(p-phenylene vinylene) (PPV), poly[2-methoxy-5-(2-ethylhexyloxy)-1,4-phenylenevinylidene] (MEH-PPV), poly[2-methoxy-5-(3′,7′-dimethyloctyloxy)-1,4-phenylenevinylidene] (MOMO-PPV), 4,4′-Bis(N-carbazolyl)-1,1′-biphenyl, N,N,N′,N′-Tetraphenylbenzidine, PEDOT:PSS, poly(N-vinyl carbazole) (PVK), polymethacrylate, poly(9,9-octylfluorene), N,N′-bis(naphthalene-1-yl)-N,N′-diphenylbenzidine (NPB), and spiro-NPB. The hole injection material may include, but is not limited to, at least one of dipyrazino[2,3-f:2′,3′-h]quinoxaline-2,3,6,7,10,11-hexacarbonitrile, PEDOT, PEDOT:PSS, a derivative doped with s-MoO₃, 4,4′,4″-Tris(N-3-methylphenyl-N-phenylamino)triphenylamine, 7,7,8,8-tetracyanoquinodimethane, copper phthalocyanine, nickel oxide, molybdenum oxide, tungsten oxide, vanadium oxide, molybdenum sulfide, tungsten sulfide, and copper oxide.

In some embodiments, a thickness of a bottom electrode is 20-200 nm; a thickness of a top electrode is 40-190 nm; a thickness of the hole injection layer 50 is 20 nm to 200 nm; a thickness of the hole transport layer 40 is 30 nm to 180 nm; a total thickness of the light-emitting layer 30 is 30 nm to 180 nm; and the electron functional layer 60 has a thickness of 10 nm to 180 nm. It will be appreciated that the bottom electrode may be one of the anode 10 and the cathode 20, and the top electrode may be the other of the anode 10 and the cathode 20.

It can be understood that the optoelectronic device 100 may also add some functional layers conventionally used for the optoelectronic device 100 to help improve the performance of the optoelectronic device 100, such as an electron blocking layer, a hole blocking layer, an interface modification layer, and the like.

It can be understood that materials of each layer of the optoelectronic device 100 can be adjusted according to the actual needs of the optoelectronic device 100.

In some embodiments, the optoelectronic device 100 may further include a substrate disposed on a side of the anode 10 or the cathode 20 facing away from the electronic functional layer 60. The substrate includes a rigid, flexible substrate, particularly glass, silicon wafer, polycarbonate, polymethyl methacrylate, polyethylene terephthalate, polyethylene naphthalate, polyamide, polyethersulfone, or a combination thereof.

In some embodiments, the optoelectronic device 100 may further include an encapsulation layer (not shown) to insulate water oxygen (for example, to make a concentration of oxygen and water below 0.1 ppm) and improve the performance stability of the optoelectronic device 100. Specifically, the sealing material used for forming the sealing layer may be selected from at least one of UV glue, metal film, glass glue, and the like. In a specific embodiment, the encapsulating material may be acrylic resin or epoxy resin.

Based on the above-described optoelectronic device 100, a method of preparing the optoelectronic device 100 is further proposed. The method includes: sequentially preparing a plurality of film layers according to a preset sequence of film layers to obtain an optoelectronic device 100. Here, the preset sequence of film layers refers to the order in which the optoelectronic devices 100 are sequentially stacked from the bottom to the top.

The method for forming the respective film layers may be a chemical method or a physical method. Among them, the chemical methods include chemical vapor deposition method, continuous ion layer adsorption and reaction method, anodic oxidation method, electrolytic deposition method and co-precipitation method. The physical methods include a physical coating method and a solution method. The physical coating method includes: a thermal evaporation coating method, an electron beam evaporation coating method, a magnetron sputtering method, a multi-arc ion coating method, a physical vapor deposition method, an atomic layer deposition method, a pulsed laser deposition method, and the like. The solution method may be a spin coating method, a printing method, an ink jet printing method, a blade coating method, a printing method, a dipping and pulling method, a soaking method, a spray coating method, a roll coating method, a casting method, a slit coating method, a strip coating method, or the like.

In some embodiments, in order to accelerate the forward aging of the device, the freshly prepared device may also be heat treated at 60-150° C. for 1 min-48 h.

In a fifth aspect, the present disclosure also relates to a display device including the optoelectronic device 100 provided by the present disclosure. The display device may be any electronic product having a display function, and the electronic product includes, but is not limited to, a smartphone, a tablet, a laptop, a digital camera, a digital video camera, a smart wearable device, a smart weighing scale, a vehicle-mounted display, a television or an electronic book reader, wherein the smart wearable device may be, for example, a smart bracelet, a smart watch, Virtual Reality (VR) helmets, etc.

Hereinafter, the present disclosure will be specifically described with reference to specific examples, and the following examples are only partial examples of the present disclosure and do not limit the present disclosure. The raw materials used in the following examples are commercially available products unless otherwise specified.

### Material Example 1

1. Zinc oleate and octadecene (ODE) were weighed in a molar ratio of 2.5:1 and placed in a 50 ml three-neck flask. They were treated under vacuum at 130° C. for 50 minutes. Then, under an argon atmosphere, the temperature was raised to 280° C. and maintained for 30 minutes to obtain a first mixture.
2. Stearyl alcohol was dissolved in ODE at 200° C. to obtain a first mixed solution having a stearyl alcohol concentration of 1 mmol/g. The first mixture prepared in step 1 was cooled down to 250° C., the first mixed solution was injected at a molar ratio of octadecanol to zinc ions of 1:0.2. The reaction was carried out for 8 minutes to obtain a second mixture.
3. Oleic acid was dissolved in ODE at 120° C. to obtain a second mixed solution having an oleic acid concentration of 0.4 mmol/g. According to the molar ratio of oleic acid to zinc ions of 1:1, the second mixed solution was injected into the second mixture, and the reaction was continued at 250° C. for 75 minutes to obtain a third mixture containing ZnO nanoparticles. The average particle size of the ZnO nanoparticles was about 4 nm by TEM (hereinafter, the average particle diameter was measured by TEM method).
4. A temperature of the third mixture was raised to 280° C., 10 ml oleic acid and 0.13 mmol NaF were added, and the reaction was carried out for 75 minutes to obtain a fourth mixture. A molar ratio of oleic acid to octadecene in step 1 was 1:1, and a molar ratio of NaF to zinc ions was 1.3:4.
5. A cleaning solution was prepared by mixing 10 ml of ethyl acetate and 15 ml of ethanol. Two tubes of this cleaning solution were prepared for use. The fourth mixture was cooled to 50° C. and added to the cleaning solution. The combined mixture was placed in a centrifuge and centrifuged at 7300 rpm for 3 minutes. After centrifugation, the supernatant was decanted. The centrifugation process was repeated, and the solid product was collected and dried to obtain the composite material ZnO@NaF. After detection, it had been found that an average particle size of ZnO@NaF was about 5.6 nm, which was equivalent to a shell thickness of about 1.6 nm.
6. ZnO@NaF was taken and dispersed in n-hexane to obtain a composite material solution with a concentration of 30 mg/ml, referred to as the n-hexane solution of ZnO@NaF.

### Material Example 2

The scheme of Material Example 2 is basically the same as that of Material Example 1, except that in step 1 of Material Example 2:
zinc oleate was changed to titanium oleate, correspondingly, the reaction product in step 5 was TiO₂@NaF, and the composite material solution in step 6 was TiO₂ @ NaF in n-hexane.

It was detected that an average particle size of TiO₂ nanoparticles was approximately 4 nm, while an average particle size of TiO₂@NaF was about 5.5 nm, corresponding to a shell thickness of approximately 1.5 nm.

### Material Example 3

The scheme of Material Example 3 is basically the same as that of Material Example 1, except that in step 4 of Material Example 3:
NaF was replaced with NaCl, and correspondingly, the reaction product in step 5 was ZnO@NaCl, and the composite material solution in step 6 was ZnO@NaCl in n-hexane.

It was detected that the average particle size of ZnO nanoparticles was approximately 4 nm, while the average particle size of ZnO@NaCl was about 5.7 nm, corresponding to a shell thickness of approximately 1.7 nm.

### Material Example 4

The scheme of Material Example 4 is basically the same as that of Material Example 1, except that in step 4 of Material Example 4:
NaF was replaced with LiF, and correspondingly, the reaction product in step 5 was ZnO@LiF, and the composite material solution in step 6 was ZnO@LiF in n-hexane.

It was detected that the average particle size of ZnO nanoparticles was approximately 4 nm, while the average particle size of ZnO@LiF was about 5.7 nm, corresponding to a shell thickness of approximately 1.7 nm.

### Material Example 5

The scheme of Material Example 5 is basically the same as that of Material Example 1, except that in step 4 of Material Example 3:
the amount of NaF charged was changed to 0.1 mmol.

It was detected that the average particle size of ZnO nanoparticles was approximately 4 nm, while the average particle size of ZnO@NaF was about 4.6 nm, corresponding to the shell thickness of approximately 0.6 nm.

### Material Example 6

The scheme of Material Example 6 is basically the same as that of Material Example 1, except that in step 4 of Material Example 6:
the amount of NaF charged was changed to 0.2 mmol.

It was detected that the average particle size of ZnO nanoparticles was approximately 4 nm, while the average particle size of ZnO@NaF was about 6.5 nm, corresponding to the shell thickness of approximately 2.5 nm.

### Material Example 7

The scheme of Material Example 7 is basically the same as that of Material Example 1, except that in step 4 of Material Example 7:
the amount of NaF charged was changed to 0.05 mmol.

It was detected that the average particle size of ZnO nanoparticles was approximately 4 nm, while the average particle size of ZnO@NaF was about 4.3 nm, corresponding to the shell thickness of approximately 0.3 nm.

### Material Example 8

The scheme of Material Example 8 is basically the same as that of Material Example 1, except that in step 4 of Material Example 8:
the amount of NaF charged was changed to 0.3 mmol.

It was detected that the average particle size of ZnO nanoparticles was approximately 4 nm, while the average particle size of ZnO@NaF was about 7.7 nm, corresponding to the shell thickness of approximately 3.7 nm.

### Material Example 9

The scheme of Material Example 9 is basically the same as that of Material Example 1, except that in step 4 of Material Example 9:
the temperature of the reaction was changed to 250° C.

It was detected that the average particle size of ZnO nanoparticles was approximately 4 nm, while the average particle size of ZnO@NaF was about 4.6 nm, corresponding to the shell thickness of approximately 0.6 nm.

### Material Example 10

The scheme of Material Example 10 is basically the same as that of Material Example 1, except that in step 4 of Material Example 10:
the temperature of the reaction was changed to 260° C.

It was detected that the average particle size of ZnO nanoparticles was approximately 4 nm, while the average particle size of ZnO@NaF was about 4.8 nm, corresponding to the shell thickness of approximately 0.8 nm.

### Material Example 11

The scheme of Material Example 11 is basically the same as that of Material Example 1, except that in step 4 of Material Example 11:
the temperature of the reaction was changed to 300° C.

It was detected that the average particle size of ZnO nanoparticles was approximately 4 nm, while the average particle size of ZnO@NaF was about 6.9 nm, corresponding to the shell thickness of approximately 2.9 nm.

### Material Comparative Example 1

The scheme of this comparative example is basically the same as that of Example 1, except that in this comparative example:
steps 4 and 5 are omitted; and
step 6 was replaced with the following steps.

A cleaning solution was prepared by mixing 10 ml of ethyl acetate and 15 ml of ethanol. Two tubes of this cleaning solution were prepared for use. The third mixture was cooled to 50° C. and added to the cleaning solution. The combined mixture was placed in a centrifuge and centrifuged at 7300 rpm for 3 minutes. After centrifugation, the supernatant was decanted. The centrifugation process was repeated, and the solid product was collected and dried to obtain ZnO.

ZnO was dispersed with n-hexane to obtain a n-hexane solution of ZnO having a concentration of 30 mg/ml.

### Material Comparative Example 2

The scheme of this comparative example is basically the same as that of Example 2, except that in this comparative example:
steps 4 and 5 are omitted; and
step 6 was replaced with the following steps.

A cleaning solution was prepared by mixing 10 ml of ethyl acetate and 15 ml of ethanol. Two tubes of this cleaning solution were prepared for use. The third mixture was cooled to 50° C. and added to the cleaning solution. The combined mixture was placed in a centrifuge and centrifuged at 7300 rpm for 3 minutes. After centrifugation, the supernatant was decanted. The centrifugation process was repeated, and the solid product was collected and dried to obtain TiO₂.

TiO₂ was dispersed with n-hexane to obtain a n-hexane solution of TiO₂ having a concentration of 30 mg/ml.

### Film Example 1

The composite material solution (the n-hexane solution of ZnO @ NaF) prepared in Material Example 1 was spin-coated on a glass substrate, and vacuum-dried to form a film to obtain a thin film with a thickness of about 35 nm.

### Film Examples 2 to 11

The scheme of Film Example n is essentially the same as that of Film Example 1, except that the composite material solution in Film Example n is the composite material solution from step 6 of Material Example n, where n is any integer from 2 to 11.

### Film Comparative Example 1

The scheme of this Film Comparative Example is basically the same as that of Film Example 1, except that the composite material solution in this Film Comparative Example is the ZnO solution from Material Comparative Example 1.

### Film Comparative Example 2

The scheme of this Film Comparative Example is basically the same as that of Film Example 1, except that the composite material solution in this Film Comparative Example is the TiO₂ solution from Material Comparative Example 2.

### Device Example 1

(1) A glass substrate with an ITO anode layer on its surface was provided, with a thickness of the anode being 80 nm.
(2) PEDOT:PSS was spin-coated onto the ITO, achieving a thickness of 20 nm, and vacuum dried to form a film, resulting in a hole injection layer.
(3) A chlorobenzene solution of TFB (with a concentration of 10 mg/mL) was spin-coated onto the hole injection layer, achieving a thickness of 20 nm, and vacuum dried to form a film, resulting in a hole transport layer.
(4) A n-hexane solution of blue quantum dots CdZnSe/CdZnSe/CdZnS (a concentration of blue quantum dots was 25 mg/mL) was spin-coated on the hole transport layer, and the thickness is 40 nm. The film is dried in vacuum to obtain a light-emitting layer. Then, the light-emitting layer was subjected to UV irradiation, and the parameters were set to a dose of 100 mJ/cm² and an illumination time of 6 min.
(5) The composite material solution (the n-hexane solution of ZnO@NaF) prepared in Material Example 1 was spin-coated on the light-emitting layer with a thickness of 35 nm, and vacuum dried to form a film to obtain an electron transport layer.
(6) A 15 nm thick translucent cathode Ag layer with a thickness of 100 nm was evaporated on the electron transport layer.
(7) After the device was prepared, the device was heat treated at 120° C. for 15 minutes to obtain the QLED.

### Device Examples 2 to 11

The scheme of Device Example n is essentially the same as that of Device Example 1, except that the composite material solution in step (5) of Device Example n is the composite material solution from step 6 of Material Example n, where n is any integer from 2 to 11.

### Device Comparative Example 1

The scheme of this Device Comparative Example is basically the same as that of Device Example 1, except that the composite material solution in step (5) of this Device Comparative Example is the ZnO solution from Material Comparative Example 1.

### Device Comparative Example 2

The scheme of this Device Comparative Example is basically the same as that of Device Example 1, except that the composite material solution in step (5) of this Device Comparative Example is the TiO₂ solution from Material Comparative Example 2.

### Experimental Example

(1) The films prepared in the Film Examples and the Film Comparative Examples were taken, and their properties were tested. The results are shown in Table 1.

The detection method is as follows.
(1) Water-oxygen stability test: After placing the film in air with a temperature of 25° C. and a humidity of 85% for 1 hour, test the band gap of the material in the film.
(2) Thermal stability test: Place the film in a vacuum environment, heat it to 85° C., and place it for 24 hours to test the band gap of the film.

Among them, the band gap detection method may be: in ultraviolet photoelectron spectroscopy (UPS), the energy difference between the top of the valence band and the Fermi level is obtained by measuring the kinetic energy of the ultraviolet photoelectron emitted from the surface of the sample to be measured. Then, combined with the Fermi level positions measured by X-ray photoelectron spectroscopy (XPS), the constant gap can be estimated.

TABLE 1

| | | band gap after | band gap |
|---|---|---|---|
| | initial | water oxygen | after thermal |
| | band | stability | stability |
| | gap (ev) | test (ev) | test (ev) |
| Film Example 1 | 3.51 | 3.49 | 3.48 |
| Film Example 2 | 3.93 | 3.90 | 3.88 |
| Film Example 3 | 3.46 | 3.40 | 3.39 |
| Film Example 4 | 3.49 | 3.46 | 3.47 |
| Film Example 5 | 3.42 | 3.37 | 3.35 |
| Film Example 6 | 3.58 | 3.57 | 3.54 |
| Film Example 7 | 3.37 | 3.22 | 3.16 |
| Film Example 8 | 3.66 | 3.65 | 3.65 |
| Film Example 9 | 3.40 | 3.31 | 3.27 |
| Film Example 10 | 3.43 | 3.37 | 3.35 |
| Film Example 11 | 3.62 | 3.61 | 3.60 |
| Film Comparative Example 1 | 3.32 | 3.13 | 3.10 |
| Film Comparative Example 2 | 3.71 | 3.54 | 3.57 |

As can be seen from the above table:

After the water-oxygen stability test and the thermal stability test, the decrease amplitude of the band gap of the Film Examples 1 to 11 is small, and the decrease amplitude of the Film Examples 1 and the Film Examples 5 to 11 is significantly smaller than that of the Film Comparative Example 1, and the decrease amplitude of the Film Example 2 is significantly smaller than that of the Film Comparative Example 2, indicating that the coating of the alkali metal halide on the surface of the metal oxide in the present disclosure helps to improve the water-oxygen stability and the thermal stability of the material.
(2) For the preparation methods provided in Device Example 1 and Device Examples 5 to 8, the materials from Material Example 1 and Material Examples 5 to 8 were used to prepare their respective corresponding single-electron devices (named single electron device 1, single electron device 5, single electron device 6, single electron device 7, and single electron device 8), and the current density-voltage curves of the single electron devices were tested. The current density at 5V for each device was compared, and the results are shown in Table 2. The preparation method for the single electron devices (EOD) is essentially the same as that for the corresponding complete QLEDs, with the only difference being the omission of the hole injection layer and the hole transport layer.

TABLE 2

| | Current Density of EOD Devices at 5 V |
|---|---|
| | (mA/cm²) |
| single electron device 1 | 2.75 |
| single electron device 5 | 4.14 |
| single electron device 6 | 1.58 |
| single electron device 7 | 5.84 |
| single electron device 8 | 0.13 |

As can be seen from the above table, with the change of the thickness of the shell layer in the used material ZnO @ NaF, the single electron device 1, the single electron device 5, the single electron device 6, the single electron device 7, and the single electron device 8 show different current densities, indicating that regulating the thickness of the shell layer composed of the alkali metal halide may regulate the tunneling effect of electrons, thereby improving its electron injection ability.
(3) Take the devices prepared in the above Device Examples and Device Comparison Examples for performance testing. The results are presented in Table 3. The test method is as follows:
(3.1) External quantum dot efficiency:

The ratio of electron-hole logarithm injected into quantum dots into the number of emitted photons, the unit is %, which is an important parameter to measure the advantages and disadvantages of electroluminescent devices, and can be obtained by measuring it by EQE optical testing instrument. The specific calculation formula is as follows:

$$EQE = {η}_{e} {η}_{r} χ \frac{{K}_{R}}{{K}_{R} + {K}_{NR}} \times 100 \%$$

where ηₑ is the optical output coupling efficiency, η_{γ} is the ratio of the number of recombined carriers to the number of injected carriers, x is the ratio of the number of excitons generated by photons to the total number of excitons, K_{R} is the radiation process rate, and K_{NR} is the non-radiation process rate.

Test conditions: carry out at room temperature with air humidity of 30˜60%.
(3.2) The test method for lifetime T95@1000 nit is: the time required for the brightness of the device to decrease to a certain proportion of the highest brightness under constant current or voltage drive. The time for the brightness to decrease to 95% of the highest brightness is defined as T95, and this lifetime is the measured lifetime. In order to shorten the test cycle, the device life test is usually carried out by accelerating device aging at high brightness, and the life at high brightness is obtained by fitting the extended exponential attenuation brightness attenuation fitting formula. For example, the life at 1000 nit is counted as T95_{1000 nit}. The specific calculation formula is as follows:

$$T {95}_{L} = T {95}_{H} \cdot {( \frac{{L}_{H}}{{L}_{L}} )}^{A}$$

Among them, T95_{L} is the lifetime at low brightness, T95_{H} is the measured lifetime at high brightness, L_{H} is the device accelerated to the highest brightness, L_{L} is 1000 nit, and A is the acceleration factor. In this experiment, the A value is 1.7 by measuring the lifetime of several groups of QLED devices at rated brightness.

The life test system is used to test the life of the corresponding devices. The test conditions are: at room temperature and the air humidity is 30˜ 60%.

TABLE 3

| | EQEₘₐₓ(%) | T95_{1000 nit}(h) |
|---|---|---|
| Device Example 1 | 20.39 | 111.0 |
| Device Example 2 | 16.59 | 51.0 |
| Device Example 3 | 17.48 | 68.2 |
| Device Example 4 | 20.02 | 101.2 |
| Device Example 5 | 18.35 | 77.1 |
| Device Example 6 | 16.62 | 56.6 |
| Device Example 7 | 15.77 | 45.4 |
| Device Example 8 | 15.27 | 33.9 |
| Device Example 9 | 12.6 | 21.4 |
| Device Example 10 | 17.11 | 56.3 |
| Device Example 11 | 14.87 | 28.4 |
| Device Comparative Example 1 | 13.17 | 2.8 |
| Device Comparative Example 2 | 11.48 | 1.7 |

As can be seen from the above table:

Compared with Device Comparative Examples 1 and 2, Device Examples 1 to 11 have obvious improvements in EQEmax and T95_{1000 nit}, indicating that the use of the above composite material to fabricate the electron transport layer in the present disclosure is beneficial to improving the luminescence performance and lifetime of the device.

The technical solutions provided by the embodiments of the present disclosure have been described in detail above, and the principles and embodiments of the present disclosure have been described herein by applying specific examples, and the description of the above embodiments is only for helping to understand the methods and core ideas of the present disclosure. Meanwhile, those skilled in the field may change the specific embodiments and the scope of application according to the ideas of the present disclosure, and in summary, the contents of the present specification should not be construed as limiting the present disclosure.

What is claimed:

1. A composite material, comprising:
a metal oxide nanoparticle; and
a shell layer coated on a surface of the metal oxide nanoparticle, a material of the shell layer comprising an alkali metal halide.

2. The composite material according to claim 1, wherein the metal oxide nanoparticle comprises one or more of an undoped oxide and a doped oxide: the undoped oxide comprises at least one of ZnO, TiO₂, SnO₂, Ga₂O₃, and Al₂O₃, an oxide in the doped oxide comprises at least one of ZnO, TiO₂, SnO₂, Ga₂O₃, and Al₂O₃, and a doping element in the doped oxide comprises at least one of Al, Mg, Li, In, and Ga.

3. The composite material according to claim 1, wherein the alkali metal halide comprises an alkali metal cation and a halogen anion, the alkali metal cation comprises one or more of Na⁺, K⁺, Li⁺, Rb⁺, Cs⁺, and Fr⁺, and the halogen anion comprises one or more of F⁻, Cl⁻, Br⁻, and I⁻.

4. The composite material according to claim 3, wherein the alkali metal halide comprises an alkali metal fluoride comprising one or more of NaF, KF, LiF, RbF, CsF, and FrF.

5. The composite material according to claim 4, wherein the metal oxide nanoparticle is a ZnO nanoparticle, and a shell layer coating the surface of the ZnO nanoparticle is a NaF shell layer.

6. The composite material according to claim 1, wherein an average particle size of the metal oxide nanoparticle ranges from 3 nm to 12 nm, a thickness of the shell layer ranges from 0.3 nm to 5 nm, and an average particle size of the composite material ranges from 3.3 nm to 17 nm.

7. A method of preparing a composite material, comprising:
providing a mixed solution, wherein the mixed solution comprises a metal oxide nanoparticle, an alkali metal halide, and an organic solvent; and
heating the mixed solution to obtain a composite material.

8. The method according to claim 7, wherein a molar ratio of the alkali metal halide to a metal element in the metal oxide nanoparticle ranges from 1:2 to 1:4.

9. The method according to claim 7, wherein the step of heating the mixed solution is operated in a temperature ranging from 260° C. to 300° C. for 60 minutes to 90 minutes.

10. The method according to claim 7, wherein the organic solvent comprises one or more of C₈-C₁₈ organic acids comprising one or more of octanoic acid, capric acid, heptanoic acid, oleic acid, stearic acid, lauric acid, myristic acid, and palmitic acid;
the metal oxide nanoparticle comprises one or more of an undoped oxide and a doped oxide: the undoped oxide comprises at least one of ZnO, TiO₂, SnO₂, Ga₂O₃, and Al₂O₃, an oxide in the doped oxide comprises at least one of ZnO, TiO₂, SnO₂, Ga₂O₃, and Al₂O₃, and a doping element in the doped oxide comprises at least one of Al, Mg, Li, In, and Ga; and
the alkali metal halide comprises an alkali metal cation and a halogen anion, the alkali metal cation comprises one or more of Na⁺, K⁺, Li⁺, Rb⁺, Cs⁺, and Fr⁺, and the halogen anion comprises one or more of F⁻, Cl⁻, Br⁻, and I⁻.

11. The method according to claim 7, wherein prior to the step of providing the mixed solution, the method further comprises:
mixing a metal precursor and a first solvent to obtain a first mixture containing an organometallic complex;
mixing a second solvent and the first mixture to obtain a second mixture containing a metal oxide nanoparticle; and
mixing the second mixture, an alkali metal halide and an organic solvent to obtain the mixed solution containing the metal oxide nanoparticle, the alkali metal halide and the organic solvent.

12. The method according to claim 11, wherein the first solvent comprises one or more of octadecene, paraffin oil, tetrahydrofuran, disilicone oil, octafluorocyclohexane, and polycyclopentadiene:
the metal precursor comprises an organic acid salt containing a metal element, the metal element comprising at least one of Zn, Ti, Sn, Ga, Al, Mg, Li, In, and Ga, and the organic acid radical in the organic acid salt comprises at least one of stearate ion, oleate ion, laurate ion, myristic ion, and palmitic ion; and,
the second solvent comprises a mixed solution of an alcohol compound and an A solvent, the alcohol compound comprises one or more of C₆-C₁₈ alcohol compounds comprising one or more of hexanol, octanol, dodecanol, tetradecanol, cetyl alcohol, and stearyl alcohol, and the A solvent comprises one or more of octadecene, paraffin oil, tetrahydrofuran, disilicone oil, octafluorocyclohexane, and polycyclopentadiene.

13. The method according to claim 12, wherein a molar ratio of the first solvent to the metal element in the metal precursor ranges from 2.2:1 to 3:1, and a molar ratio of the organic solvent to the first solvent ranges from 1:1 to 1:1.2.

14. The method according to claim 11, wherein the step of mixing a metal precursor and a first solvent to obtain a first mixture containing an organometallic complex comprises: mixing the metal precursor and the first solvent at a first temperature ranging from 120° C. to 140° C. in a vacuum room for a first time period; and
injecting inert gas into the vacuum room to make the metal precursor reacting with the first solvent at a second temperature ranging from 270° C. to 290° C. for a second time period.

15. The method according to claim 14, wherein the first time period ranges from 25 minutes to 60 minutes, the second time period ranges from 25 minutes to 60 minutes.

16. The method according to claim 12, wherein the step of mixing the second solvent and the first mixture and reacting to obtain a second mixture containing a metal oxide nanoparticle comprises:
mixing the second solvent and the first mixture in a third temperature for a third time period to obtain a reaction mixture; and
mixing a third solvent and the reaction mixture in a fourth temperature for a fourth time period to obtain a third mixture containing a metal oxide nanoparticle.

17. The method according to claim 16, wherein a molar ratio of the alcohol compound in the second solvent to the metal element in the metal precursor ranges from 1:0.15 to 1:0.25;
the third temperature ranges from 240° C. to 260° C.;
the third time period ranges from 5 minutes to 10 minutes;
the third solvent comprises a mixed solution of an acid compound and a B solvent, the acid compound comprises one or more of C₈-C₁₈ organic acids comprising one or more of octanoic acid, capric acid, heptanoic acid, oleic acid, stearic acid, lauric acid, myristic acid, and palmitic acid, and the B solvent comprises one or more of octadecene, paraffin oil, tetrahydrofuran, disilicone oil, octafluorocyclohexane, and polycyclopentadiene;
the fourth temperature ranges from 240° C. to 260° C.; and,
the fourth time period ranges from 60 minutes to 90 minutes.

18. The method according to claim 17, wherein a molar ratio of the acid compound in the third solvent to the metal element in the metal precursor ranges from 1:0.8 to 1:1.

19. An optoelectronic device comprising an anode, an electronic functional layer, and a cathode disposed in a stack, wherein the electronic functional layer comprises a thin film, a material of the thin film comprising a composite material that comprises a metal oxide nanoparticle and a shell layer coated on the surface of the metal oxide nanoparticle, a material of the shell layer comprising an alkali metal halide.

20. The optoelectronic device according to claim 19, wherein the anode and the cathode are each independently selected from one of a doped metal oxide particle electrode, a composite electrode of metal and metal oxide, a graphene electrode, a carbon nanotube electrode, a metal electrode or an alloy electrode, and a material of the doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide, the composite electrode of metal and metal oxide is selected from AZO/Ag/AZO, AZO/Al/AZO, ITO/Ag/ITO, ITO/Al/ITO, ZnO/Ag/ZnO, ZnO/Al/ZnO, TiO/Ag/TiO₂, TiO₂/Al/TiO₂, ZnS/Ag/ZnS, ZnS/Al/ZnS, and a material of the metal electrode is selected from one or more of Ag, Al, Cu, Mo, Au, Pt, Si, Ca, Mg and Ba; and
the optoelectronic device further comprises a light-emitting layer disposed between the anode and the electronic functional layer, and a material of the light-emitting layer is selected from organic light-emitting materials or quantum dot light-emitting materials; the organic light-emitting materials are selected from one or more of 4,4′-bis(N-carbazole)-1,1′-biphenyl: tris[2-(p-tolyl)pyridine]iridium (III), 4,4′,4″-tris(carbazole-9-yl)triphenylamine: tris[2-(p-tolyl)pyridine]iridium, diarylanthracene derivatives, stilbene aromatic derivative, pyrene derivative, fluorene derivative, TBPe fluorescent material, TTPX fluorescent material, TBRb fluorescent material, DBP fluorescent material, delayed fluorescent material, TTA material, thermal activation delayed material, polymers containing B-N covalent bonding, hybrid local charge transfer excited state material, and exciplex luminescent material; the quantum dot light-emitting materials are selected from at least one of a single structure quantum dot, a core-shell structure quantum dot, and a perovskite type semiconductor material, and the core-shell structure quantum dot has one or more shell layers; a material of the single structure quantum dot, a core material of the core-shell structure quantum dot, and a shell material of the core-shell structure quantum dot are selected from at least one of a Group II-VI compound, a Group IV-VI compound, a Group III-V compound, and a Group I-III-VI compound; the Group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the Group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the Group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the Group I-III-VI compound is selected from one or more of CuInS₂, CuInSe₂, and AgInS₂; the perovskite type semiconductor is selected from one of a doped inorganic perovskite type semiconductor, an undoped inorganic perovskite type semiconductor, and an organic-inorganic hybrid perovskite type semiconductor, a general structure formula of the inorganic perovskite type semiconductor is AMX₃, wherein A is Cs⁺, M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻; a general structure formula of the organic-inorganic hybrid perovskite type semiconductor is BMX₃, wherein B is an organic amine cation selected from CH₃(CH₂)ₙ₋₂NH₃⁺ (n≥2) or NH₃(CH₂)ₙNH₃²⁺ (n≥2), Mis a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻.
